(19) United States
(12) Patent Application Publication
(10) Pub. No.: US 2019/0304944 A1
(43) Pub. Date: Oct. 3, 2019

(54) ELECTRICALLY CONDUCTIVE BONDING MATERIAL AND METHOD FOR MANUFACTURING SEMICONDUCTOR DEVICE

(71) Applicant: TANAKA KIKINZOKU KOGYO K.K., Chiyoda-ku, Tokyo (JP)

(72) Inventors: Rikia FURUSHO, Hiratsuka-shi, Kanagawa (JP); Shintaroh ABE, The Cavendish (SG); Takeshi KONDO, Hiratsuka-shi, Kanagawa (JP); Teruki TANAKA, Hiratsuka-shi, Kanagawa (JP)

(21) Appl. No.: 16/465,881

(22) PCT Filed: Dec. 1, 2017
(86) PCT No.: PCT/JP2017/043350

§ 371 Date: May 31, 2019

(30) Foreign Application Priority Data
Dec. 2, 2016 (JP) 2016-235326

(51) Int. Cl. H01L 23/00; H01B 1/22; B22F 7/08

(52) U.S. Cl. CPC H01L 24/29; H01L 24/83; H01B 1/22; B22F 7/08; B22F 2301/255; H01L 2924/2075; H01L 2924/20751; H01L 2924/20752; H01L 2224/83203; H01L 2224/29139

(57) ABSTRACT

The present invention provides an electrically conductive bonding material having a high bonding strength and a high thermal conductivity, and capable of forming a bonding layer providing a very low porosity under low pressurization. The present invention relates to an electrically conductive bonding material which bonds a chip and an adherend under pressure, the electrically conductive bonding material containing silver particles; silver compound particles; and a dispersant, wherein the silver particles and the silver compound particles are present in a weight ratio of 30:70 to 70:30, and the electrically conductive bonding material provide a porosity of 15% or less after the chip and the adherend are subject to pressurizing-bond under an air atmosphere of pressure of 10 MPa and 280° C. for 5 minutes.

### TECHNICAL FIELD

The present invention relates to an electrically conductive bonding material and a method for manufacturing a semiconductor device using the electrically conductive bonding material.

### BACKGROUND ART

In a semiconductor device, a bonding material having conductivity is used as a die attachment material for bonding semiconductor chips. Silver powders are commonly used for electrically conductive bonding materials due to high electrical conductivity and antioxidant property thereof, and many reports have been made on adhesives containing silver powders and pasty bonding materials bonded by sintering.

For example, Patent Document 1 reports an electrically conductive paste containing silver, silver oxide, and an organic compound having a property of reducing the silver oxide, in order to reduce the contact resistance between silver fine particles.

In addition, Patent Document 2 discloses an electrically conductive bonding material, in a total amount of 99.0 wt % to 100 wt %, containing silver particles, silver oxide particles, and a dispersant containing an organic matter having 30 or less carbon atoms. Metal bonding can be performed at a lower temperature for a bonded portion by using silver powders and silver oxide powders having an average particle diameter of 0.1 μm to 100 μm as the electrically conductive bonding material.

### CITED REFERENCES

Patent Document
Patent Document 1: JP-A-2005-267900
Patent Document 2: JP-A-2010-257880

### DISCLOSURE OF INVENTION

### Problems to be Solved by the Invention

However, the electrically conductive paste described in Patent Document 1 vigorously reacts with the organic compound having a reduction property, and decomposition gas of the organic compound and oxygen gas due to the reduction of the silver compound are generated in a large amount. Therefore, irregular voids are formed in the obtained electrically conductive paste, which becomes a stress concentration point, so that the electrically conductive paste is easily broken, and there is a danger of handling.

In addition, the electrically conductive bonding material described in Patent Document 2 is bonded without pressure, so that the porosity is high between porous layers after bonding. Therefore, over-sintering occurs at high temperature aging at 200° C. or higher, the bonding layer is observed to be sparse, and the heat resistance is insufficient.

There is a method of reducing the porosity of the bonding layer with a very high pressure in order to lower the porosity, but in this case, the pressure is as high as 30 MPa or more, and the element may be damaged.

Accordingly, an object of the present invention is to provide an electrically conductive bonding material having a high bonding strength and a high thermal conductivity, and capable of forming a bonding layer having a very low porosity under low pressurization.

### Means for Solving the Problems

As a result of studies for achieving the above object, the present inventors found that the above problem can be solved by an electrically conductive bonding material for bonding a chip and an adherend under pressure, the electrically conductive bonding material which contains silver particles and silver compound particles in a specific range of the weight ratio, and from which a bonding layer can be formed to have a very low porosity under pressure lower than that of a conventional pressurization method. Thus, the present invention is completed.

The present invention is as follows.

[1] An electrically conductive bonding material for bonding a chip and an adherend under pressure, the electrically conductive bonding material comprising:

silver particles;

silver compound particles; and

a dispersant, wherein

the silver compound particles are compound particles that decompose into at least silver and an oxidizing substance by heating,

the silver particles and the silver compound particles are present in a weight ratio of 30:70 to 70:30, and

the electrically conductive bonding material provides a porosity of 15% or less after the chip and the adherend being subject to pressure-bond under an air atmosphere of pressure of 10 MPa and 280° C. for 5 minutes.

[2] The electrically conductive bonding material according to [1], wherein the porosity is 5% or less.
[3] The electrically conductive bonding material according to [1] or [2], wherein the silver particles are spherical particles having an average particle diameter of 0.1 μm to 30 μm and a tap density of 3 g/cc or more, or scaly particles having an aspect ratio of 1.0 to 100, an average particle diameter of 0.1 μm to 10 μm and a tap density of 3 g/cc or more.
[4] The electrically conductive bonding material according to any one of [1] to [3], wherein the silver compound particles and the dispersant are present in a weight ratio of 100:0.5 to 100:50.
[5] The electrically conductive bonding material according to any one of [1] to [4], further comprising a solvent.
[6] The electrically conductive bonding material according to any one of [1] to [5], wherein the dispersant is at least one compound selected from the group consisting of alcohols, carboxylic acids and amines.
[7] A method for manufacturing a semiconductor device, the method comprising:

a step of bonding a chip and an adherend via an electrically conductive bonding material, wherein

the electrically conductive bonding material contains silver particles, silver compound particles and a dispersant, the silver particles and the silver compound particles are present in a weight ratio of 30:70 to 70:30,

in the bonding step, pressurization treatment is performed at 4 MPa to 30 MPa and 200° C. to 350° C. for 1 to 30 minutes, and

the electrically conductive bonding material provides a porosity of 10% or less after the bonding step.

### Effect of the Invention

After the electrically conductive bonding material of the present invention is sintered under heat and pressure, the bonding layer provides the low porosity and is closer to a bulk (metal bonded body). Therefore, a high bonding strength and a high thermal conductivity can be achieved in the electrically conductive bonding material. Based on the high thermal conductivity, the electrically conductive bonding material of the present invention is excellent in heat dissipation property.

### BRIEF DESCRIPTION OF DRAWINGS

FIG. 1 is a drawing substitute photograph of a SEM photograph after the electrically conductive bonding material of Example 1 was subject to pressurizing-bond under an air atmosphere pressure of 10 MPa at 280° C. for 5 minutes.

FIG. 2 is a drawing substitute photograph of a SEM photograph after the electrically conductive bonding material of Comparative Example 1 was subject to pressurizing-bond under an air atmosphere pressure of 10 MPa at 280° C. for 5 minutes.

### EMBODIMENTS FOR CARRYING OUT THE INVENTION

Hereinafter, the embodiments for carrying out the present invention are described. However, the present invention is not limited to the following embodiments and can be arbitrarily modified and implemented without departing from the gist of the present invention. In the present specification, “-” indicating the numerical range is used to include the numerical values described before and after the numerical range as the lower limit and the upper limit.

<Electrically Conductive Bonding Material>

The electrically conductive bonding material of the present invention for bonding a chip and an adherend under pressure, the electrically conductive bonding material contains silver particles, silver compound particles, and a dispersant, wherein the silver particles and the silver compound particles are present in a weight ratio of 30:70 to 70:30, and the electrically conductive bonding material provides a porosity of 15% or less after the chip and the adherend are subject to pressurizing-bond under an air atmosphere of pressure of 10 MPa and 280° C. for 5 minutes.

(Silver Particles and Silver Compound Particles)

The silver particles in the present invention have both electrical conductivity and bonding property. Although the melting point of silver is about 960° C., sintering at a low temperature of 200° C. to 300° C. can be done by combining the silver compound particles and the dispersant, and the adherend can be bonded by metal bonding at an interface of the adherend.

The shape of the silver particles is not particularly limited. It is preferable that the silver particles are spherical particles having an average particle diameter of 0.1 μm to 30 μm and a tap density of 3 g/cc or more, or scaly particles having an aspect ratio of 1.0 to 100, an average particle diameter of 0.1 μm to 10 μm and a tap density of 3 g/cc or more.

In a case where the silver particles are spherical, an average particle diameter of 30 μm or less is preferable since the dispersant covering the silver particles is easy to remove and the sinterability is enhanced. When the average particle diameter is less than 0.1 μm, the productivity and cost may be disadvantageous, and it is unsuitable for large chips with large shrinkage during sintering. In the case where the silver particles are spherical, the average particle diameter is more preferably 0.3 μm to 10 μm. The average particle diameter means the particle diameter of the volume integrated 50% diameter D50 measured by laser diffraction.

The tap density of the spherical silver particles is preferably 3 g/cc or more from the viewpoint of lowering the porosity before heating, and the tap density of the spherical silver particles is more preferably 4.5 g/cc or more. In addition, the upper limit of the tap density is generally 8 g/cc or less. The tap density means a density when the silver particles are placed in a container and tapped for 500 times.

The spherical shape of the silver particles is not limited to a true spherical shape, and may include a slightly distorted spherical shape if acute projections are not included. For example, an ellipsoidal or a polyhedron may even be included in a spherical shape as long as it is close to a spherical shape. It can be determined the particles are spherical as long as the aspect ratio thereof measured by scanning electron microscope observation is 0.95 to 1.05.

In a case where the silver particles are scaly, an aspect ratio of 1.0 to 100, an average particle diameter of 0.1 μm to 10 μm and a tap density of 3 g/cc or more are preferable from the viewpoint of lowering the porosity before heating. The aspect ratio is more preferably 1.0 to 5.0, the average particle diameter is more preferably 0.5 μm to 6 μm, and the tap density is more preferably 4.5 g/cc or more. The upper limit of the tap density is generally 8 g/cc or less. In the case where the silver particles are scaly, the thickness is preferably 0.1 μm to 5 μm, and more preferably 0.5 μm to 3 μm.

The aspect ratio and the thickness of the silver particles can be measured by scanning electron microscope observation. In addition, the average particle diameter and the tap density can be determined under the same conditions as described above.

Further, for example, silver nanoparticles or irregular silver particles such as wire-like, needle-like or crown-like shape may be added as the silver particles, as long as the properties of the electrically conductive bonding material according to the present invention are not hindered.

The silver compound particles not particularly limited as long as they are compound particles that decompose into at least silver and an oxidizing substance by heating. As the silver compound particles, for example, silver oxide particles, silver carbonate particles, silver neodecanoate particles and the like can be used, and one or plural types of silver compound particles can be used. Among these, the silver oxide particles are preferred from the viewpoint of a high silver content in the silver compound. In a case of using plural types of silver compound particles, a plurality of silver compounds of one type having different shapes and sizes may be used, or a plurality of silver compounds of different types may be used.

The oxidizing substance generated by the decomposition of the silver compound particles promotes the combustion of the dispersant covering the silver particles. In addition, since silver generated by the decomposition of silver compound particles is fine and the surface thereof is spotless, the sinterability thereof is better than that of the silver particles. The pressurization performed at the same time reduces the space generated by reduction, and a bonding layer having a very low porosity can be formed under low pressurization.

When the silver compound particles are decomposed into at least silver and an oxidizing substance by heating, the volume decreases according to the type of the silver compound particles. Therefore, voids are formed when the silver compound particles are reduced to silver in the portion where the silver compound particles were present. However, the electrically conductive bonding material according to the present invention is used under pressurization, so that at the same time as the voids are formed, the voids are crushed by the pressure and an electrically conductive bonding material providing a low porosity after pressurizing-bonding is obtained. Since the porosity is low, the electrically conductive bonding material is closer to a metal bulk. Thus, the bonding strength and the thermal conductivity are improved.

For example, in a case where the silver compound particles are silver oxide particles, when silver oxide is decomposed into silver and oxygen, the volume is reduced by about 60% due to the reduction from the silver oxide particles to silver. Due to this decrease in volume, an electrically conductive bonding material providing a low porosity after pressurizing-bonding is obtained.

The shape and size of the silver compound particles are not particularly limited, and as the size, an average particle diameter of 0.2 μm to 20 μm is preferred from the viewpoint of sinterability.

The silver particles and the silver compound particles are present in a weight ratio of 30:70 to 70:30, and preferably 40:60 to 60:40.

When the ratio of the silver compound particles to the total amount of the silver particles and the silver compound particles is set to 30 wt % or more, the voids formed during the reduction to silver are crushed by pressurization at the same time. Thus, the porosity after pressurizing-bonding is lowered, and as a result, a bonding surface excellent in bonding strength and thermal conductivity is formed as compared with the case where there are few silver compound particles.

When the porosity in the bonding layer is high, over-sintering occurs at high temperature aging at 200° C. or higher, the bonding layer is observed to be sparse, and the heat resistance is insufficient. When the porosity of the bonding layer is to be lowered by a very high pressure, the semiconductor element may be damaged.

In addition, when the ratio of the silver compound particles to the total amount of the silver particles and the silver compound particles is set to 70 wt % or less, the effect of suppressing voids and outgas generated by decomposition of the silver compound particles is obtained.

(Dispersant)

The dispersant in the present invention is also called a lubricant and is a compound which covers the surface of the silver particles and/or the silver compound particles to prevent aggregation of the silver particles and/or the silver compound particles. The combustion of the dispersant is promoted by the oxidizing substance generated by the decomposition of the silver compound particles.

The dispersant may previously cover the surface of the silver particles and/or the silver compound particles, or may cover the surface after being added to a mixture containing the silver particles and the silver compound particles.

The dispersant may be any one conventionally used, and examples thereof include stearic acid and oleic acid. Among these, the dispersant is preferably at least one compound selected from the group consisting of alcohols, carboxylic acids and amines from the viewpoint of dispersibility and easy combustibility. One dispersant may be used, or a plurality of dispersants may be used in combination.

The alcohols may be a compound having a hydroxyl group, and examples thereof include a linear or branched alkyl alcohol having 3 to 30 carbon atoms. The alcohols may be any of primary alcohols, secondary alcohols and tertiary alcohols, or may be diols and alcohols having a cyclic structure. Among these, isostearyl alcohol and octyldodecanol are more preferred from the viewpoint of dispersibility.

The carboxylic acids may be a compound containing a carboxylic acid, and examples thereof include a linear or branched alkylcarboxylic acid having 3 to 30 carbon atoms. The carboxylic acids may be any of primary carboxylic acids, secondary carboxylic acids and tertiary carboxylic acids, or may be dicarboxylic acids or carboxy compounds having a cyclic structure. Among these, neodecanoic acid, oleic acid, and stearic acid are more preferred from the viewpoint of dispersibility.

The amines may be a compound containing an amino group, and examples thereof include an alkylamine having 3 to 30 carbon atoms. The amines may be any of primary amines, secondary amines and tertiary amines, or may be an amine having a cyclic structure. Among these, stearylamine and laurylamine are preferred from the viewpoint of dispersibility.

The dispersant containing the alcohols, the carboxylic acids and the amines may be in the form of an aldehyde group, an ester group, a sulfanyl group, a ketone group, a quaternary ammonium salt or the like. For example, when the carboxylic acid covers the surface of the silver particles and/or the silver compound particles, a carbonyl salt forms.

Whether the silver particles and/or the silver compound particles are covered with the dispersant can be confirmed by infrared spectroscopic measurement. That is, when the functional group of the compound which is a dispersant is bonded to the silver particles and/or the silver compound particles, the type of the dispersant can be specified based on the detected peak since the peak position appearing differs depending on the type of the functional group being bonded.

The silver compound particles and the dispersant are preferably present in a weight ratio in the range of 100:0.1 to 100:100, and more preferably in the range of 100:0.5 to 100:50. When the dispersant is 0.1 part by weight or more based on 100 parts by weight of the silver compound particles, a good dispersion state of the silver particles and/or the silver compound particles can be maintained. In addition, when the dispersant is less than or equal to 100 parts by weight based on 100 parts by weight of the silver compound particles, the residual organic matter can be eliminated.

(Solvent)

The electrically conductive bonding material according to the present invention may further contain a solvent for making the electrically conductive bonding material pasty. The solvent is not particularly limited as long as it can make the electrically conductive bonding material pasty. A solvent having a boiling point of 350° C. or lower is preferred because the solvent easily volatilizes when the chip and the adherend are bonded in the manufacture of a semiconductor device described later, and a solvent having a boiling point of 300° C. or lower is more preferred.

Specific examples include acetates, ethers, and hydrocarbons. More specifically, dibutyl carbitol, butyl carbitol acetate, mineral split and the like are preferably used.

Based on the electrically conductive bonding material, the solvent is usually 3 wt % to 20 wt %, and preferably 5 wt % to 10 wt % from the viewpoint of workability.

(Others)

The electrically conductive bonding material according to the present invention may be added with a fatty acid compound, electrically conductive particles, an inorganic filler, a precipitation inhibitor, a rheology control agent, a bleed inhibitor, a defoamer, or the like in a scope not impairing the effects of the present invention.

By adding a fatty acid compound, the silver compound particles are more easily to be decomposed. As the fatty acid compound, for example, a neodecanoic acid compound or a stearic acid compound is preferred. One type of the fatty acid compound may be added or plural types of the fatty acid compounds may be added, and it is preferable that the fatty acid compound is contained in a total amount of 0.01 wt % to 5 wt % based on the electrically conductive bonding material.

Examples of the electrically conductive particles include platinum, gold, palladium, copper, nickel, tin, indium, an alloy of the above metals, graphite, carbon black, those plated with the above metals, and inorganic or organic particles plated with the metals. One type of the electrically conductive particles may be added or plural types of the electrically conductive particles may be added, and it is preferable that the electrically conductive particles are contained in an amount of 0.01 wt % to 5 wt % based on the electrically conductive bonding material.

Examples of the inorganic filler include silica and silicon carbide. One type of the inorganic filler may be added or plural types of the inorganic filler may be added, and it is preferable that the inorganic filler is contained in an amount of 0.01 wt % to 5 wt % based on the electrically conductive bonding material.

Examples of the precipitation inhibitor include fumed silica and a thickener. One type of the precipitation inhibitor may be added or plural types of the precipitation inhibitor may be added, and it is preferable that the precipitation inhibitor is contained in an amount of 0.01 wt % to 5 wt % based on the electrically conductive bonding material.

Examples of the rheology control agent include a urea-based rheology control agent and bentonite. One type of the rheology control agent may be added or plural types of the rheology control agent may be added, and it is preferable that the rheology control agent is contained in an amount of 0.01 wt % to 5 wt % based on the electrically conductive bonding material.

Examples of the bleed inhibitor include a fluorine-based bleed inhibitor. One type of the bleed inhibitor may be added or plural types of the bleed inhibitor may be added, and it is preferable that the bleed inhibitor is contained in an amount of 0.01 wt % to 5 wt % based on the electrically conductive bonding material.

Examples of the defoamer include a fluorine-based defoamer and a silicone-based defoamer. One type of the bleed inhibitor may be added or plural types of the bleed inhibitor may be added, and it is preferable that the bleed inhibitor is contained in an amount of 0.01 wt % to 5 wt % based on the electrically conductive bonding material.

The electrically conductive bonding material according to the present invention provide a porosity of 15% or less after the chip and the adherend are subject to pressure-bond by using the electrically conductive bonding material containing the silver particles and the silver compound particles under an air atmosphere of pressure of 10 MPa and 280° C. for 5 minutes.

Specifically, the electrically conductive bonding material is placed on a silver-plated copper lead frame. A 3 mm×3 mm silver sputtering silicon chip mounted thereon is pressurizing-bonded under an air atmosphere condition of 10 MPa and 280° C. for 5 minutes using a die bonder DB500 LS (manufactured by Adwelds). The porosity of the electrically conductive bonding material after the pressurizing-bond can be measured by binarizing the SEM photograph of the cross section of the bonding layer. In detail, a region of 20 μm×50 μm on the bonding layer on the SEM photograph can be binarized to calculate the area ratio of the void portion. The porosity is preferably 5% or less, and more preferably 1% or less.

In addition, since the electrically conductive bonding material according to the present invention can lower the porosity, excellent bonding strength and thermal conductivity can be obtained.

The method for measuring the bonding strength is not particularly limited, and includes, for example, a method for measuring die shear strength as will be described later in the examples. A load is applied to the bonded chip in the shear direction, and the strength at breakage is taken as the bonding strength. As a device for measuring the bonding strength, Series 4000 manufactured by Nordson Dage can be used, for example, and the measurement is performed under a test speed of 200 mm/sec at 25° C.

In the case of performing pressurizing-bond under the same conditions as above, i.e., performing the measurement under a test speed of 200 mm/sec at 25° C., the bonding strength is preferably 40 MPa or more, and more preferably 50 MPa or more.

The method for measuring the thermal conductivity is not particularly limited, and, for example, the thermal conductivity can be obtained by the following equation by a laser flash method as will be described later in the examples.

Thermal conductivity λ=thermal diffusivity a×specific gravity d×specific heat Cp

Laser pulse light is irradiated to a bonded sample, the temperature change on the back side is measured, and the thermal diffusivity a is obtained from this temperature change behavior. The thermal conductivity λ (W/m·K) is calculated by the above equation from the thermal diffusivity a, the specific gravity d and the specific heat Cp. The thermal diffusivity a can be measured using a thermal constant measuring device of a laser flash method. For example, TC-7000 manufactured by ULVAC-RIKO can be used. The specific heat Cp can be measured using a differential scanning calorimeter. For example, DSC 7020 manufactured by Seiko Instruments Inc. can be used to measure the specific heat Cp at room temperature according to JIS-K 7123.

In the case of performing pressurizing-bond under the same conditions as above, the thermal conductivity is preferably 250 W/m·K or more, more preferably 300 W/m·K or more, and still more preferably 350 W/m·K or more.

<Method for Manufacturing Electrically Conductive Bonding Material>

The electrically conductive bonding material according to the present invention can be obtained by mixing the silver particles, the silver compound particles and the dispersant. The dispersant may be added either before or after the mixing, and thereby at least one of the silver particles and silver compound particles is covered with the dispersant.

The mixing may be dry or wet using a solvent, and a mortar, a planetary ball mill, a roll mill, a propellerless mixer or the like can be used.

<Method for Manufacturing Semiconductor Device>

The electrically conductive bonding material according to the present invention can be suitably used for a method for manufacturing a semiconductor device in which a chip and an adherend are bonded. That is, the method for manufacturing a semiconductor device includes a step of bonding a chip and an adherend via the electrically conductive bonding material according to the present invention.

Examples of the adherend include a lead frame, a DBC board, and a printed circuit board.

In the bonding step, pressurization treatment is performed at 4 MPa to 30 MPa and 200° C. to 350° C. for 1 to 30 minutes, and the electrically conductive bonding material provide a porosity of 10% or less after the bonding step.

The pressurizing-bond can be performed under an air atmosphere, a nitrogen atmosphere, a reducing atmosphere such as hydrogen, etc., and the air atmosphere is preferred from the viewpoint of productivity.

In the bonding step, the pressure is preferably 4 MPa or more, and more preferably 10 MPa or more, from the viewpoint of the porosity. The upper limit of the pressure is preferably 30 MPa or less, and more preferably 20 MPa or less, from the viewpoint of preventing damage to the chip.

In the bonding step, the temperature is preferably 200° C. or higher, and more preferably 250° C. or higher, from the viewpoint of the porosity. The upper limit of the temperature is preferably 350° C. or lower, and more preferably 300 or lower, from the viewpoint of preventing damage to peripheral members.

In the bonding step, the time of pressurization or heating is preferably 1 minute or longer from the viewpoint of the porosity, and more preferably 30 minutes or shorter from the viewpoint of preventing damage to peripheral members and providing productivity.

In the bonding using the electrically conductive bonding material according to the present invention, the pressurization and heating are indispensable. By heating, the silver compound particles are subject to reductive decomposition to generate a decomposed matter containing silver and an oxidizing substance. The oxidizing substance promotes the combustion of the dispersant. In addition, since the silver generated by the reduction of the silver compound particles is fine and the surface thereof is spotless, the sinterability thereof is better than that of the silver particles. Therefore, the sinterability of silver is better and the chip and the adherend are bonded better compared to a case of only using the silver particles.

When the silver particles and the silver compound particles are present in the electrically conductive bonding material in a weight ratio of 30:70 to 70:30, since the proportion of the silver compound particles is large, the influence of the volume shrinkage along with the decomposition of the silver compound particles also increases, in addition to the improvement of the sinterability of silver as described above. The voids formed by the volume shrinkage are immediately crushed even at a relatively low pressure of 4 MPa to 30 MPa, and a low porosity such as 10% or less in porosity can be achieved.

Due to this low porosity, the electrically conductive bonding material after bonding is close to a metal bulk, so that a semiconductor device having both high bonding strength and high thermal conductivity and excellent heat dissipation property can be obtained.

### EXAMPLES

Hereinafter, the present invention will be further described with reference to Examples, but the present invention is not limited to the following Examples.

### [Porosity]

A cross section of a bonding layer of a bonded sample is observed by SEM. A region of 20 μm×50 μm in the bonding layer on the obtained SEM photograph was binarized using image analysis software Image J and the porosity was calculated from the area ratio of the void portion.

### [Bonding Strength]

The bonded sample was measured for die shear strength under a test speed of 200 mm/sec at 25° C., using a bonding strength measurement device [“Series 4000” (product name), manufactured by Nordson Dage].

### [Thermal Conductivity]

The thermal diffusivity a was measured in accordance with ASTM-E 1461 using a thermal constant measuring device of a laser flash method (TC-7000 manufactured by ULVAC-RIKO), the specific gravity d at room temperature was calculated by a pycnometer method, and the specific heat Cp at room temperature was measured in accordance with JIS-K 7123 using a differential scanning calorimeter (DSC 7020, manufactured by Seiko Instruments Inc.). Therefore, the thermal conductivity λ (W/m·K) was calculated by the following equation from the thermal diffusivity a, the specific gravity d and the specific heat Cp. The results are shown in Table 1.

Thermal conductivity λ=thermal diffusivity a×specific gravity d×specific heat Cp

### Example 1

Silver powder manufactured by Tanaka Kikinzoku Kogyo K.K., having a spherical particle shape, an average particle diameter of 1.0 μm, and a tap density of 5 g/cc was prepared as silver particles.

In addition, silver oxide powder (product name: AY 6059) manufactured by Tanaka Kikinzoku Kogyo K.K., having a granular particle shape and an average particle diameter of 10 μm was prepared as silver compound particles.

The mixing ratio of the silver particles and the silver oxide particles was adjusted such that the ratio of the content of the silver compound particles to the content of the silver particles in the electrically conductive bonding material was the ratio shown in Table 1.

The silver particles, the silver oxide particles, dibutyl carbitol as a solvent, and neodecanoic acid as a dispersant were respectively mixed in the contents shown in Table 1, and thereafter the mixture was kneaded using a three-roll mill to prepare an electrically conductive bonding material.

The obtained electrically conductive bonding material was coated onto a 12×12 mm² silver-plated copper lead frame, and a 3 mm×3 mm silver sputtering silicon chip was placed on the coated surface. Thereafter, the 3 mm×3 mm silver sputtering silicon chip was vertically pressurized under an air atmosphere of 10 MPa and heated at 280° C. for 5 minutes, so as to prepare a silver bonded body of a semiconductor device.

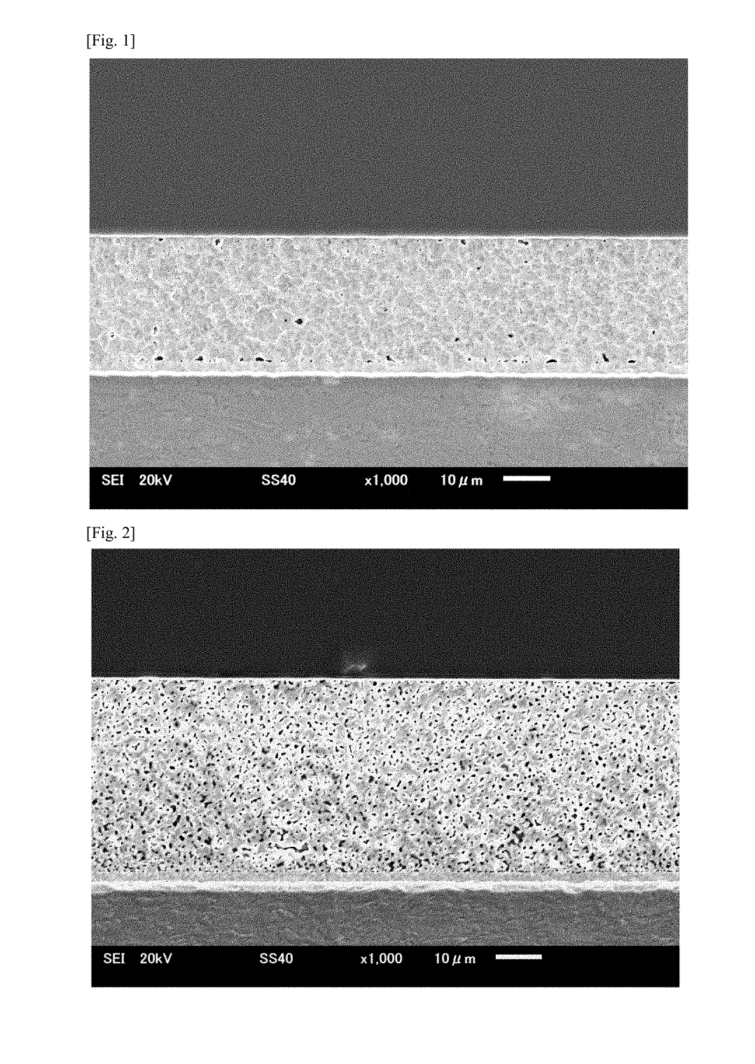

The porosity, the bonding strength, and the thermal conductivity of the obtained silver bonded body are measured, and the results are shown in Table 1. In addition, the SEM photograph is shown in FIG. 1.

### Example 21

A silver bonded body of a semiconductor device was prepared in the same manner as in Example 1, except that silver powder manufactured by Tanaka Kikinzoku Kogyo K.K., having a scaly particle shape, an aspect ratio of 4, an average particle diameter of 2.2 μm, and a tap density of 6.2 g/cc was prepared as silver particles. The porosity, the bonding strength, and the thermal conductivity of the obtained silver bonded body are shown in Table 1.

### Example 31

A silver bonded body of a semiconductor device was prepared in the same manner as in Example 1, except that the amounts of the silver particles, the silver compound particles and the dispersant were changed to the amounts shown in Example 3 of Table 1. The porosity, the bonding strength, and the thermal conductivity of the obtained silver bonded body are measured, and the results are shown in Table 1.

### Example 4

A silver bonded body of a semiconductor device was prepared in the same manner as in Example 1, except that the amounts of the silver particles, the silver compound particles and the dispersant were changed to the amounts shown in Example 4 of Table 1. The porosity, the bonding strength, and the thermal conductivity of the obtained silver bonded body are measured, and the results are shown in Table 1.

### Comparative Example 1

A silver bonded body of a semiconductor device was prepared in the same manner as in Example 1, except that the amounts of the silver particles, the silver compound particles and the dispersant were changed to the amounts shown in Comparative Example 1 of Table 1. The porosity, the bonding strength, and the thermal conductivity of the obtained silver bonded body are measured, and the results are shown in Table 1. In addition, the SEM photograph is shown in FIG. 2.

### Comparative Example 2

A silver bonded body of a semiconductor device was prepared in the same manner as in Example 1, except that the amounts of the silver particles, the silver compound particles and the dispersant were changed to the amounts shown in Comparative Example 2 of Table 1. The porosity, the bonding strength, and the thermal conductivity of the obtained silver bonded body are measured, and the results are shown in Table 1.

TABLE 1

| | | |
|---|---|---|
| Silver particles | Silver compound particles | Dispersant |

| | | Amount | | | Amount | | Amount |
|---|---|---|---|---|---|---|---|
| Experimental | | (parts by | | | (parts by | | (parts by |
| examples | Shape | weight) | Type | Shape | weight) | Type | weight) |
| Example 1 | Spherical | 50 | Silver | Average | 50 | Neodecanoic | 2.5 |
| | Average particle | | oxide | particle | | acid | |
| | diameter: 1 μm | | | diameter: | | | |
| | Tap density: 5 g/cc | | | 10 μm | | | |
| Example 2 | Scaly | 50 | Silver | Average | 50 | Neodecanoic | 2.5 |
| | Aspect ratio: 4 | | oxide | particle | | acid | |
| | Average particle | | | diameter: | | | |
| | diameter: 2.2 μm | | | 10 μm | | | |
| | Tap density: 6.2 g/cc | | | | | | |
| Example 3 | Spherical | 70 | Silver | Average | 30 | Neodecanoic | 1.5 |
| | Average particle | | oxide | particle | | acid | |
| | diameter: 1 μm | | | diameter: | | | |
| | Tap density: 5 g/cc | | | 10 μm | | | |
| Example 4 | Spherical | 30 | Silver | Average | 70 | Neodecanoic | 3.5 |
| | Average particle | | oxide | particle | | acid | |
| | diameter: 1.0 μm | | | diameter: | | | |
| | Tap density: 5 g/cc | | | 10 μm | | | |
| Comparative | Spherical | 80 | Silver | Average | 20 | Neodecanoic | 1 |
| Example 1 | Average particle | | oxide | particle | | acid | |
| | diameter: 1 μm | | | diameter: | | | |
| | Tap density: 5 g/cc | | | 10 μm | | | |
| Comparative | Spherical | 20 | Silver | Average | 80 | Neodecanoic | 4 |
| Example 2 | Average particle | | oxide | particle | | acid | |
| | diameter: 1 μm | | | diameter: | | | |
| | Tap density: 5 g/cc | | | 10 μm | | | |

| | Solvent | | | | |
|---|---|---|---|---|---|
| | | Amount | | | Thermal |
| Experimental | | (parts by | Porosity | Strength | conductivity |
| examples | Type | weight) | (%) | (MPa) | (W/m · K) |
| Example 1 | Dibutyl | 7 | 1 or less | 50 | 350 |
| | carbitol | | | | |
| Example 2 | Dibutyl | 7 | 1 or less | 50 | 350 |
| | carbitol | | | | |
| Example 3 | Dibutyl | 7 | 1 or less | 50 | 300 |
| | carbitol | | | | |
| Example 4 | Dibutyl | 7 | 1 or less | 50 | 300 |
| | carbitol | | | | |
| Comparative | Dibutyl | 7 | 20 | 35 | 200 |
| Example 1 | carbitol | | | | |
| Comparative | Dibutyl | 7 | 20 | 35 | 200 |
| Example 2 | carbitol | | | | |

From the above results, it is understood that the silver bonded bodies in Examples have remarkably lower porosity, higher bonding strength and higher thermal conductivity as compared with the silver bonded bodies in Comparative Examples.

While the present invention has been described in detail using specific embodiments, it will be apparent to those skilled in the art that various modifications and variations are possible without departing from the spirit and scope of the invention. This application is based on Japanese patent application (Japanese Patent Application No. 2016-235326) filed on Dec. 2, 2016, the entirety of which is incorporated by reference.

1. An electrically conductive bonding material for bonding a chip and an adherend under pressure, the electrically conductive bonding material comprising:
silver particles;
silver compound particles; and
a dispersant, wherein
the silver compound particles are compound particles that decompose into at least silver and an oxidizing substance by heating,
the silver particles and the silver compound particles are present in a weight ratio of 30:70 to 70:30, and
the electrically conductive bonding material provides a porosity of 15% or less after the chip and the adherend being subject to pressure-bond under an air atmosphere of pressure of 10 MPa and 280° C. for 5 minutes.

2. The electrically conductive bonding material according to claim 1, wherein the porosity is 5% or less.

3. The electrically conductive bonding material according to claim 1, wherein the silver particles are spherical particles having an average particle diameter of 0.1 μm to 30 μm and a tap density of 3 g/cc or more, or scaly particles having an aspect ratio of 1.0 to 100, an average particle diameter of 0.1 μm to 10 μm and a tap density of 3 g/cc or more.

4. The electrically conductive bonding material according to claim 1, wherein the silver compound particles and the dispersant are present in a weight ratio of 100:0.5 to 100:50.

5. The electrically conductive bonding material according to claim 1, further comprising a solvent.

6. The electrically conductive bonding material according to claim 1, wherein the dispersant is at least one compound selected from the group consisting of alcohols, carboxylic acids and amines.

7. A method for manufacturing a semiconductor device, the method comprising:
a step of bonding a chip and an adherend via an electrically conductive bonding material, wherein
the electrically conductive bonding material contains silver particles, silver compound particles and a dispersant, the silver compound particles are compound particles that decompose into at least silver and an oxidizing substance by heating, the silver particles and the silver compound particles are present in a weight ratio of 30:70 to 70:30,
in the bonding step, pressurization treatment is performed at 4 MPa to 30 MPa and 200° C. to 350° C. for 1 to 30 minutes, and
the electrically conductive bonding material provides a porosity of 10% or less after the bonding step.
